(19) United States
(12) Patent Application Publication
(10) Pub. No.: US 2007/0210278 A1
(43) Pub. Date: Sep. 13, 2007

(54) Compositions for chemical mechanical polishing silicon dioxide and silicon nitride

(76) Inventors: Sarah J. Lane, Elkton, MD (US); Charles Yu, Wilmington, DE (US)

Correspondence Address: ROHM AND HAAS ELECTRONIC MATERIALS;CMP HOLDINGS, INC., 451 BELLEVUE ROAD, NEWARK, DE, 19713, US

(21) Appl. No.: 11/372,321

(22) Filed: Mar. 8, 2006

(51) Int. Cl. C09K 13/00; H01L 21/461

(52) U.S. Cl. 252/79.1; 252/79.4; 438/692

(57) ABSTRACT

The present invention provides an aqueous composition useful for polishing silica and silicon nitride on a semiconductor wafer comprising by weight percent 0.01 to 5 carboxylic acid polymer, 0.02 to 6 abrasive, 0.01 to 10 polyvinylpyrrolidone, 0.005 to 5 cationic compound, 0.005 to 5 zwitterionic compound and balance water, wherein the polyvinylpyrrolidone has a average molecular weight between 100 grams/mole to 1,000,000 grams/mole.

### BACKGROUND OF THE INVENTION

The invention relates to chemical mechanical planarization (CMP) of semiconductor wafer materials and, more particularly, to CMP compositions for polishing silica and silicon nitride from semiconductor wafers in shallow trench isolation (STI) processes.

Decreasing dimensions of devices and the increasing density of integration in microelectronic circuits have required a corresponding reduction in the size of isolation structures. This reduction places a premium on reproducible formation of structures that provide effective isolation, while occupying a minimum amount of the substrate surface.

The STI technique is a widely used semiconductor fabrication method for forming isolation structures to electrically isolate the various active components formed in integrated circuits. One major advantage of using the STI technique over the conventional LOCOS (Local Oxidation of Silicon) technique is the high scalability to CMOS (Complementary Metal-Oxide Semiconductor) IC devices for fabrication at the submicron level of integration. Another advantage is that the STI technique helps prevent the occurrence of the so-called bird's beak encroachment, which is characteristic to the LOCOS technique for forming isolation structures.

In the STI technique, the first step is the formation of a plurality of trenches at predefined locations in the substrate, usually by anisotropic etching. Next, silica is deposited into each of these trenches. The silica is then polished by CMP, down to the silicon nitride (stop layer) to form the STI structure.

Currently, there are various slurries available for the STI application. The first generation slurry (“Gen-I”) typically consists of ceria abrasives and a dispersant. The Gen-I slurry is a low cost and simple system, which provides high removal rates and throughput. However, the Gen-I slurry is not suitable for technology nodes of 130 nm and below due to excessive nitride erosion and trench dishing. The second generation slurry (“Gen-II”) typically contains chemical additives in addition to the ceria and dispersant, as in Gen I. Chemical additives serve to enhance silicon oxide to silicon nitride removal selectivity, providing excellent clearing ability, while moderating nitride erosion and suppressing trench dishing. This Gen-II slurry is the most widely implemented STI slurry today for the 130 nm and sub-130 nm nodes. Nevertheless, challenges arise when approaching more advanced technology nodes (e.g., sub-90 nm) in areas such as dishing and nitride erosion due to pattern dependency in the slurry's removal behavior. The third generation slurry (“Gen-III”) is the so-called “stop-on-planar” or “reverse Prestonian” slurry. The Gen-III slurry typically contains a chemical additive that has a strong affinity to the silicon oxide surface in an aqueous environment, and exhibits “kinetic” adsorption behavior. The Gen-III slurry can have a pronounced oxide removal threshold (non-Prestonian) or its oxide removal rate may diminish over time. The Gen-III slurry is designed for advanced STI applications to address the pattern dependency during polishing by first selectively removing the topography. However, such a design approach generates its own challenges during implementation. For example, the Gen-III slurry has not been widely adapted due to its inability to clear active features. As a result, the Gen-III slurry typically needs to be used in combination with another slurry (e.g., a Gen-II slurry) for clearing.

Kido et al., in U.S. Patent App. Pub. No. 2002/0045350, discloses a known abrasive composition for polishing a semiconductor device comprising a cerium oxide and a water soluble organic compound. Optionally, the composition may contain a viscosity adjusting agent, a buffer, a surface active agent and a chelating agent, although, none are specified. Although, the composition of Kido provides adequate polishing performance, the ever-increasing density of integration in microelectronic circuits demand improved compositions and methods.

Hence, what is needed is a composition for chemical-mechanical polishing of silicon dioxide (“silica”) and silicon nitride for shallow trench isolation processes having both improved clearing performance while providing improved selectivity and controllability during the polishing process.

### STATEMENT OF THE INVENTION

In a first aspect, the present invention provides an aqueous composition useful for polishing silica and silicon nitride on a semiconductor wafer comprising by weight percent 0.01 to 5 carboxylic acid polymer, 0.02 to 6 abrasive, 0.01 to 10 polyvinylpyrrolidone, 0.005 to 5 cationic compound, 0.005 to 5 zwitterionic compound and balance water, wherein the polyvinylpyrrolidone has an average molecular weight between 100 grams/mole to 1,000,000 grams/mole.

In a second aspect, the present invention provides an aqueous composition useful for polishing silica and silicon nitride on a semiconductor wafer comprising by weight percent 0.01 to 5 carboxylic acid polymer, 0.02 to 6 ceria, 0.01 to 10 polyvinylpyrrolidone, 0.005 to 5 ethanolamine, 0.005 to 5 betaine and balance water, wherein the polyvinylpyrrolidone has an average molecular weight between 100 grams/mole to 1,000,000 grams/mole.

### BRIEF DESCRIPTION OF THE DRAWINGS

FIGS. 1A, 1B, 1C illustrates the clearing performance of the slurry of the present invention;

FIG. 2 illustrates the stop-on-planar performance of the slurry of the present invention;

FIG. 3 illustrates the step-height reduction performance of the slurry of the present invention;

FIGS. 4A, 4B, 4C illustrate the direct STI performance of the slurry of the present invention; and

FIG. 5 further illustrates the step-height reduction performance of the slurry of the present invention.

### DETAILED DESCRIPTION OF THE INVENTION

The composition and method provide both unexpected suppression of removal and clearing for active layers on a semiconductor wafer for shallow trench isolation processes. The composition advantageously comprises an abrasive, dispersant, planarization aid and a performance enhancer for improved selectivity and controllability during the polishing process. In particular, the present invention provides an aqueous composition useful for polishing silica and silicon nitride on a semiconductor wafer comprising ceria, carboxylic acid polymer, polyvinylpyrrolidone and balance water. The compound of the present invention further contains a cationic compound to promote planarization, regulate wafer-clearing time and silica removal. Also, the composition contains a zwitterionic compound to promote planarization and serve as a suppressant to nitride removal.

Advantageously, the novel polishing composition contains about 0.01 to 10 weight percent of polyvinylpyrrolidone to provide the pressure threshold response during oxide removal. Preferably, the polyvinylpyrrolidone is present in an amount of 0.015 to 5 weight percent. More preferably, the polyvinylpyrrolidone is present in an amount of 0.02 to 0.5 weight percent. In addition, blends of higher and lower number average molecular weight polyvinylpyrrolidone may be used.

Also, the weight average molecular weight of the polyvinylpyrrolidone is 100 to 1,000,000 grams/mole as determined by gel permeation chromatography (GPC). Preferably, the polyvinylpyrrolidone has a weight average molecular weight of 500 to 500,000 grams/mole. More preferably, the weight average molecular weight for the polyvinylpyrrolidone is about 1,500 to about 10,000 grams/mole.

In addition to the polyvinylpyrrolidone, the composition advantageously contains 0.01 to 5 weight percent of a carboxylic acid polymer to serve as a dispersant for the abrasive particles (discussed below). Preferably, the composition contains 0.05 to 1.5 weight percent of a carboxylic acid polymer. Also, the polymer preferably has a number average molecular weight of 4,000 to 1,500,000. In addition, blends of higher and lower number average molecular weight carboxylic acid polymers can be used. These carboxylic acid polymers generally are in solution but may be in an aqueous dispersion. The carboxylic acid polymer may advantageously serve as a dispersant for the abrasive particles (discussed below). The number average molecular weight of the aforementioned polymers are determined by GPC.

The carboxylic acid polymers are preferably formed from unsaturated monocarboxylic acids and unsaturated dicarboxylic acids. Typical unsaturated monocarboxylic acid monomers contain 3 to 6 carbon atoms and include acrylic acid, oligomeric acrylic acid, methacrylic acid, crotonic acid and vinyl acetic acid. Typical unsaturated dicarboxylic acids contain 4 to 8 carbon atoms and include the anhydrides thereof and are, for example, maleic acid, maleic anhydride, fumaric acid, glutaric acid, itaconic acid, itaconic anhydride, and cyclohexene dicarboxylic acid. In addition, water soluble salts of the aforementioned acids also can be used.

Particularly useful are “poly(meth)acrylic acids” having a number average molecular weight of about 1,000 to 1,500,000 preferably 3,000 to 250,000 and more preferably, 20,000 to 200,000. As used herein, the term “poly(meth)acrylic acid” is defined as polymers of acrylic acid, polymers of methacrylic acid or copolymers of acrylic acid and methacrylic acid. Blends of varying number average molecular weight poly(meth)acrylic acids are particularly preferred. In these blends or mixtures of poly(meth)acrylic acids, a lower number average molecular weight poly(meth)acrylic acid having a number average molecular weight of 1,000 to 100,000 and preferably, 4,000 to 40,000 is used in combination with a higher number average molecular weight poly(meth)acrylic acid having a number average molecular weight of 150,000 to 1,500,000, preferably, 200,000 to 300,000. Typically, the weight percent ratio of the lower number average molecular weight poly(meth)acrylic acid to the higher number average molecular weight poly(meth)acrylic acid is about 10:1 to 1:10, preferably 5:1 to 1:5, and more preferably, 3:1 to 2:3. A preferred blend comprises a poly(meth)acrylic acid having a number average molecular weight of about 20,000 and a poly(meth)acrylic acid having a number average molecular weight of about 200,000 in a 2:1 weight ratio.

In addition, carboxylic acid containing copolymers and terpolymers can be used in which the carboxylic acid component comprises 5-75% by weight of the polymer. Typical of such polymer are polymers of (meth)acrylic acid and acrylamide or methacrylamide; polymers of (meth)acrylic acid and styrene and other vinyl aromatic monomers; polymers of alkyl (meth)acrylates (esters of acrylic or methacrylic acid) and a mono or dicarboxylic acid, such as, acrylic or methacrylic acid or itaconic acid; polymers of substituted vinyl aromatic monomers having substituents, such as, halogen (i.e., chlorine, fluorine, bromine), nitro, cyano, alkoxy, haloalkyl, carboxy, amino, amino alkyl and a unsaturated mono or dicarboxylic acid and an alkyl (meth)acrylate; polymers of monethylenically unsaturated monomers containing a nitrogen ring, such as, vinyl pyridine, alkyl vinyl pyridine, vinyl butyrolactam, vinyl caprolactam, and an unsaturated mono or dicarboxylic acid; polymers of olefins, such as, propylene, isobutylene, or long chain alkyl olefins having 10 to 20 carbon atoms and an unsaturated mono or dicarboxylic acid; polymers of vinyl alcohol esters, such as, vinyl acetate and vinyl stearate or vinyl halides, such as, vinyl fluoride, vinyl chloride, vinylidene fluoride or vinyl nitriles, such as, acrylonitrile and methacrylonitrile and an unsaturated mono or dicarboxylic acid; polymers of alkyl (meth) acrylates having 1-24 carbon atoms in the alkyl group and an unsaturated monocarboxylic acid, such as, acrylic acid or methacrylic acid. These are only a few examples of the variety of polymers that can be used in the novel polishing composition of this invention. Also, it is possible to use polymers that are biodegradeable, photodegradeable or degradeable by other means. An example of such a composition that is biodegradeable is a polyacrylic acid polymer containing segments of poly(acrylate comethyl 2-cyanoacrylate).

Advantageously, the polishing composition contains 0.2 to 6 weight percent abrasive to facilitate silica removal. Within this range, it is desirable to have the abrasive present in an amount of greater than or equal to 0.5 weight percent. Also, desirable within this range is an amount of less than or equal to 2.5 weight percent.

The abrasive has an average particle size of 50 to 200 nanometers (nm). For purposes of this specification, particle size refers to the average particle size of the abrasive. More preferably, it is desirable to use an abrasive having an average particle size of 80 to 150 nm. Decreasing the size of the abrasive to less than or equal to 80 nm, tends to improve the planarization of the polishing composition, but, it also tends to decrease the removal rate.

Example abrasives include inorganic oxides, inorganic hydroxides, metal borides, metal carbides, metal nitrides, polymer particles and mixtures comprising at least one of the foregoing. Suitable inorganic oxides include, for example, silica (SiO₂), alumina (Al₂O₃), zirconia (ZrO₂), ceria (CeO₂), manganese oxide (MnO₂), or combinations comprising at least one of the foregoing oxides. Modified forms of these inorganic oxides, such as, polymer-coated inorganic oxide particles and inorganic coated particles may also be utilized if desired. Suitable metal carbides, boride and nitrides include, for example, silicon carbide, silicon nitride, silicon carbonitride (SiCN), boron carbide, tungsten carbide, zirconium carbide, aluminum boride, tantalum carbide, titanium carbide, or combinations comprising at least one of the foregoing metal carbides, boride and nitrides. Diamond may also be utilized as an abrasive if desired. Alternative abrasives also include polymeric particles and coated polymeric particles. The preferred abrasive is ceria.

The compounds provide efficacy over a broad pH range in solutions containing a balance of water. This solution's useful pH range extends from at least 4 to 9. In addition, the solution advantageously relies upon a balance of deionized water to limit incidental impurities. The pH of the polishing fluid of this invention is preferably from 4.5 to 8, more preferably a pH of 5.5 to 7.5. The acids used to adjust the pH of the composition of this invention are, for example, nitric acid, sulfuric acid, hydrochloric acid, phosphoric acid and the like. Exemplary bases used to adjust the pH of the composition of this invention are, for example, ammonium hydroxide and potassium hydroxide.

In addition, the composition advantageously contains 0.005 to 5 weight percent zwitterionic compound to promote planarization and serve as a suppressant to nitride removal. Advantageously, the composition contains 0.01 to 1.5 weight percent zwitterionic compound.

The term “zwitterionic compound” means a compound containing cationic and anionic substituents in approximately equal proportions joined by a physical bridge, for example, a CH₂ group, so that the compound is net neutral overall. The zwitterionic compounds of the present invention include the following structure: 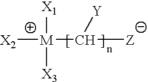
wherein n is an integer, Y comprises hydrogen or an alkyl group, Z comprises carboxyl, sulfate or oxygen, M comprises nitrogen, phosphorus or a sulfur atom, and X₁, X₂ and X₃ independently comprise substituents selected from the group comprising, hydrogen, an alkyl group and an aryl group.

As defined herein, the term “alkyl” (or alkyl- or alk-) refers to a substituted or unsubstituted, straight, branched or cyclic hydrocarbon chain that preferably contains from 1 to 20 carbon atoms. Alkyl groups include, for example, methyl, ethyl, propyl, isopropyl, cyclopropyl, butyl, iso-butyl, tert-butyl, sec-butyl, cyclobutyl, pentyl, cyclopentyl, hexyl and cyclohexyl.

The term “aryl” refers to any substituted or unsubstituted aromatic carbocyclic group that preferably contains from 6 to 20 carbon atoms. An aryl group can be monocyclic or polycyclic. Aryl groups include, for example, phenyl, naphthyl, biphenyl, benzyl, tolyl, xylyl, phenylethyl, benzoate, alkylbenzoate, aniline, and N-alkylanilino.

Preferred zwitterionic compounds include, for example, betaines. A preferred betaine of the present invention is N,N,N-trimethylammonioacetate, represented by the following structure:

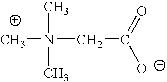

Advantageously, the composition of the present invention may comprise 0.005 to 5 weight percent cationic compound. Preferably, the composition optionally comprises 0.01 to 1.5 weight percent cationic compound. The cationic compound of the present invention may advantageously promote planarization, regulate wafer-clearing time and serve to suppress oxide removal. Preferred cationic compounds include, alkyl amines, aryl amines, quaternary ammonium compounds and alcohol amines. Exemplary cationic compounds include, methylamine, ethylamine, dimethylamine, diethylamine, trimethylamine, triethylamine, aniline, tetramethylammoniumhydroxide, tetraethylammoniumhydroxide, ethanolamine and propanolamine.

Accordingly, the present invention provides a composition useful for polishing silica and silicon nitride on a semiconductor wafer for shallow trench isolation processes. In particular, the present invention provides an aqueous composition useful for polishing silica and silicon nitride on a semiconductor wafer comprising by weight percent 0.01 to 5 carboxylic acid polymer, 0.02 to 6 abrasive, 0.01 to 10 polyvinylpyrrolidone, 0.005 to 5 cationic compound, 0.005 to 5 zwitterionic compound and balance water, wherein the polyvinylpyrrolidone has a average molecular weight between 100 grams/mole to 1,000,000 grams/mole. The composition exhibits particularly improved threshold pressure response and clearing performance at a pH range of 4 to 9.

### EXAMPLES

All example solutions contained, by weight percent, 1.8 ceria, 0.27 polyacrylic acid, 0.5 betaine and 0.15 ethanolamine. In addition, the examples of the invention contained 0.1 weight percent polyvinylpyrrolidone. The slurry was prepared by combining an abrasive package with a chemical package. The abrasive package was made by dissolving the polyacrylic acid concentrate in deionized water using a blade mixer and adding the ceria concentrate into the polyacrylic acid solution. Then, the ceria-polyacrylic acid-water mixture was titrated using nitric acid or ammonium hydroxide. The mixture was then fed into a high shear Kady Mill. The chemical package was prepared by dissolving all remaining chemicals into deionized water, in proper amounts, mixing with a blade mixer and titrating to the final pH as desired using nitric acid or ammonium hydroxide. The final slurry is prepared by mixing the abrasive package with the chemical package and titrating to the desired pH.

The patterned wafers were STI-MIT-864™ masks from Praesagus, Inc. with HDP and LPCVD-SiN films. The MIT-864 mask design had 20 mm by 20 mm die consisting of 4 mm by 4 mm features. The features in the mask had 100 μm pitches with densities ranging from 10% to 100% each, and 50% densities with pitches ranging from 1 to 1000 μm. Here, 50% density is defined as the spaces in an array of repeated structures wherein the space width/(space width+line width)×100%=50%. For example, if the space width+line width=1000 microns, the 50% space has a width of 500 microns. IC1000™ polishing pads were used for all tests. An Applied Materials Mirra® 200 mm polishing machine using an IC1000™ polyurethane polishing pad (Rohm and Haas Electronic Materials CMP Inc., of Newark, Del.) under downforce conditions of 1.5 psi and a polishing solution flow rate of 150 cc/min, a platen speed of 52 RPM and a carrier speed of 50 RPM planarized the samples. The polishing solutions had a pH of 6.5 adjusted with nitric acid or ammonium hydroxide. All solutions contained a balance of deionized water. Oxide and nitride film thicknesses were measured using an Opti-probe® 2600 metrology tool from Therma-Wave, Inc.

### Example 1

### Comparison of Clearing Performance

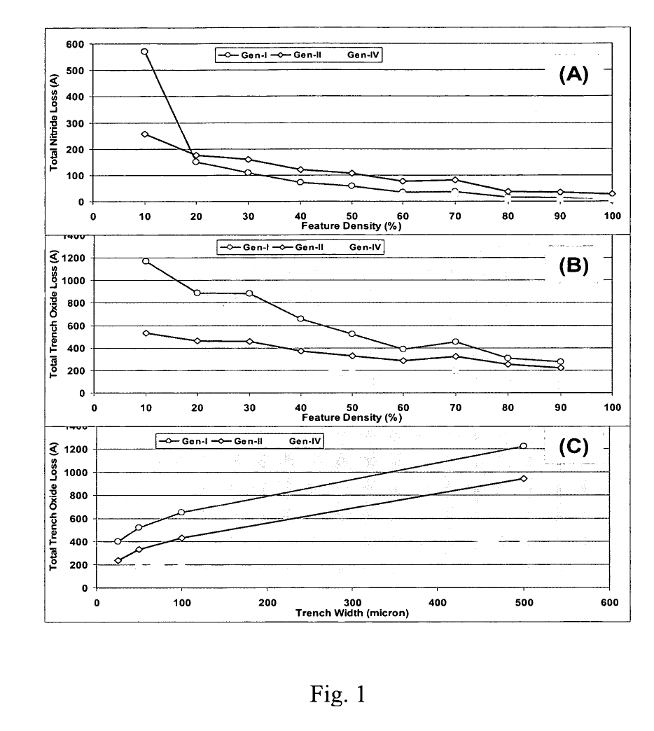

As illustrated in FIGS. 1A, 1B and 1C, a comparison of Gen-I, Gen-II and Gen-IV slurries was conducted at a removal rate of 1800 Å/min to assess their clearing performance. Gen-III slurry was excluded for its lack of clearing capability. The data presented in FIG. 1 are averages of post polishing results from center, middle and edge dies for retaining degree of wafer scale uniformify information. Among all three, Gen-IV had the lowest nitride loss (FIG. 1A). Gen-I had a lower overall nitride loss than Gen-II, except for the 10% feature where Gen-I nitride loss was higher. Also, Gen-IV was the best performing slurry, followed by Gen-II, in terms of dishing and erosion for various density features, as well as wide trenches, on MIT wafers (FIGS. 1B and 1C). Total trench oxide loss reflects the combination of dishing and erosion.

### Example 2

### Comparison of Stop-on-Planar Capability

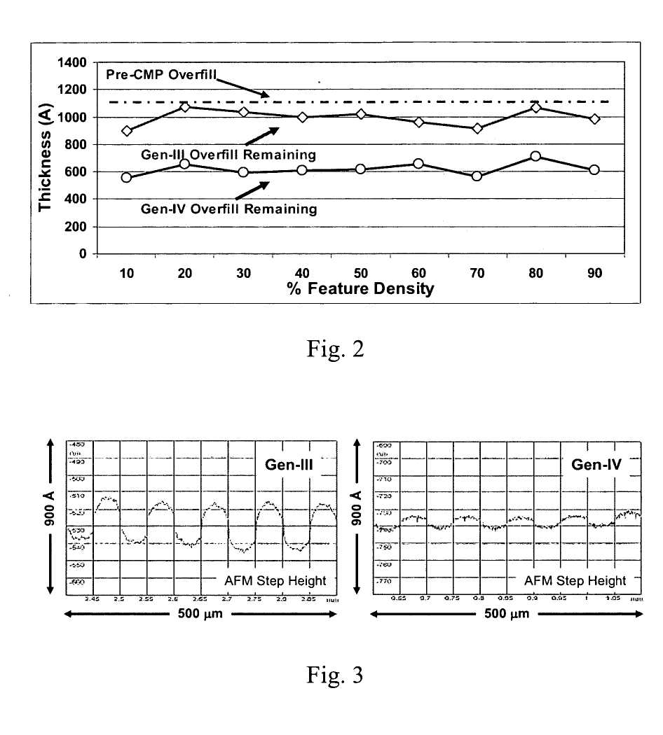

As illustrated in FIGS. 2 and 3, Gen-III and Gen-IV slurries were evaluated for their stop-on-planar capability. Gen I and Gen II slurries were excluded for their lack of stop-on-planar capability. FIG. 2 shows post polishing (under stop-on-planar mode) oxide overfills remaining for the two slurries. The data provided were averages of center, middle and edge die results. Both slurries performed well in terms of planarization. Gen-III slurry provided a “hard” stop, as shown by the post polishing overfill thicknesses, which are near their pre-CMP level. Gen-IV provided a “soft” stop, as shown by the post polishing overfill thicknesses, which lie half way between pre-CMP thickness and clearing (zero) thickness. For Gen-IV, the stopping thickness (post polishing overfill remaining) can be controlled by the aggressiveness of polishing condition. FIG. 3 shows post polishing AFM topographies of a 100 μm pitch 50% feature on a MIT wafer, showing step-height remaining for Gen-III and Gen-IV slurries. As shown, the Gen-IV slurry provided a much better step height reduction performance.

### Example 3

### Comparison of DSTI Performance

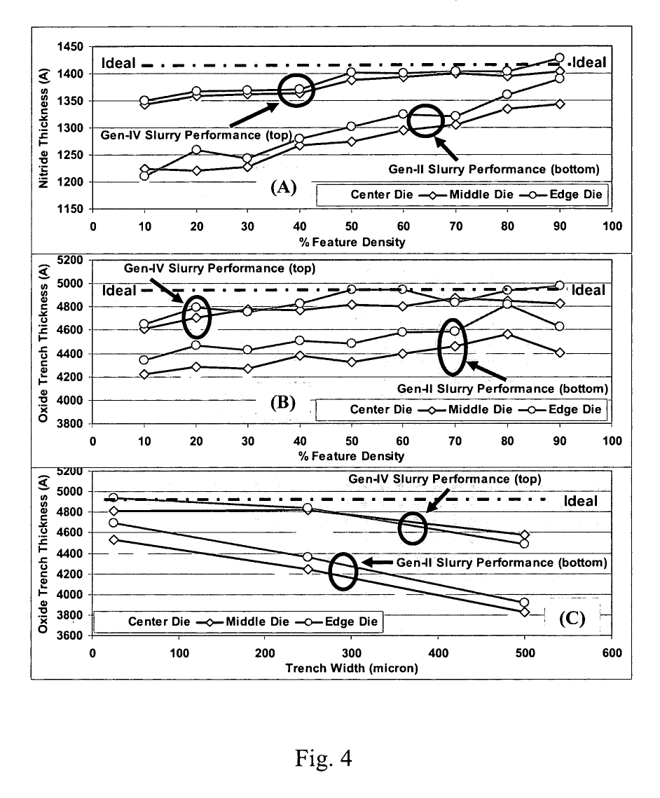

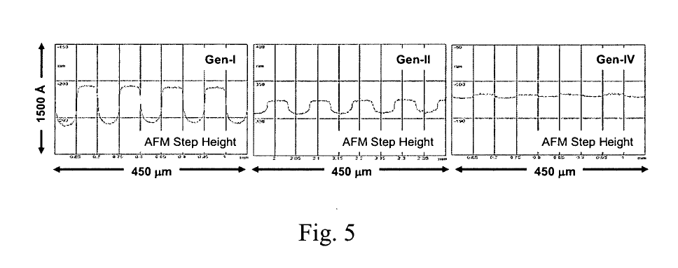

As illustrated in FIGS. 4A-C and 5, a direct comparison of DSTI performance resulted in distinct improvements of Gen-IV over Gen-II for nitride loss and total oxide loss in both density features and wide trenches. As shown in FIGS. 4A-C, the MIT wafers took less than 3 minutes to clear in both (Gen-II and Gen-IV) cases. Data from center, middle and edge dies were individually plotted to reveal wafer scale uniformity information. Utilizing the Gen-IV slurry with an un-optimized process, the post CMP nitride loss of the most challenging feature (100 μm pitch 50% density) was about 70 Å. The post CMP total trench oxide loss of the most challenging feature (500 μm trench) was about 350 Å. FIG. 5 shows the post CMP AFM topography plots of the typical 100 μm pitch, 50% density feature on MIT mask polished using Gen-I, Gen-II and Gen-IV slurries. Gen-I slurry provided a post CMP step height of about 500 Å. The Gen-II slurry provided a step height reduction to about 200 Å. Gen-IV slurry further reduced the step height to less than 50 Å.

Accordingly, the present invention provides a composition useful for polishing silica and silicon nitride on a semiconductor wafer for shallow trench isolation processes. The composition provides a “hybrid” behavior, capable of both “stop-on-planar” and clearing active features. The composition advantageously comprises an abrasive, dispersant, planarization aid and a performance enhancer for improved selectivity and controllability during the polishing process. In particular, the present invention provides an aqueous composition useful for polishing silica and silicon nitride on a semiconductor wafer comprising ceria, carboxylic acid polymer, polyvinylpyrrolidone and balance water. The compound of the present invention further contains performance enhancers, including, a cationic compound to promote planarization, regulate wafer-clearing time and silica removal and a zwitterionic compound to promote planarization and serve as a suppressant to nitride removal.

1. An aqueous composition useful for polishing silica and silicon nitride on a semiconductor wafer for shallow trench isolation processes comprising by weight percent 0.01 to 5 carboxylic acid polymer, 0.02 to 6 abrasive, 0.01 to 10 polyvinylpyrrolidone, 0.005 to 5 cationic compound, 0.005 to 5 zwitterionic compound and balance water, wherein the polyvinylpyrrolidone has a weight average molecular weight between 100 grams/mole to 1,000,000 grams/mole, wherein the aqueous composition is capable of reducing a step height on a patterned shallow trench isolation wafer.

2. The aqueous composition of claim 1 wherein the composition comprises 0.02 to 1 weight percent polyvinylpyrrolidone.

3. The aqueous composition of claim 1 wherein the polyvinylpyrrolidone has a weight average molecular weight between 1,500 grams/mole to 10,000 grams/mole.

4. The aqueous composition of claim 1 wherein the zwitterionic compound has the following structure: 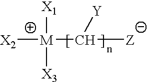
wherein n is an integer, Y comprises hydrogen or an alkyl group, Z comprises carboxyl, sulfate or oxygen, M comprises nitrogen, phosphorus or a sulfur atom, and X₁, X₂ and X₃ independently comprise substituents selected from the group comprising, hydrogen, an alkyl group and an aryl group.

5. The aqueous composition of claim 1 wherein the carboxylic acid polymer is a polyacrylic acid.

6. The aqueous composition of claim 1 wherein the cationic compound is selected from the group comprising: alkyl amines, aryl amines, quaternary ammonium compounds and alcohol amines.

7. The aqueous composition of claim 1 wherein the abrasive is ceria.

8. The aqueous composition of claim 1 wherein the aqueous composition has a pH of 4 to 9.

9. An aqueous composition useful for polishing silica and silicon nitride on a semiconductor wafer for shallow trench isolation processes comprising by weight percent 0.01 to 5 carboxylic acid polymer, 0.02 to 6 ceria, 0.01 to 10 polyvinylpyrrolidone, 0.005 to 5 ethanolamine, 0.005 to 5 betaine and balance water, wherein the polyvinylpyrrolidone has a weight average molecular weight between 100 grams/mole to 1,000,000 grams/mole, wherein the aqueous composition is capable of reducing a step height on a patterned shallow trench isolation wafer.

10. The aqueous composition of claim 9 wherein the composition comprises 0.02 to 1 weight percent polyvinylpyrrolidone.

11. The aqueous composition of claim 1, wherein the aqueous composition is capable of reducing the step height on a patterned shallow trench isolation wafer to less than 50 Å, measured with an atomic force microscope, using a 200 mm polishing machine and a polyurethane polishing pad under a downforce condition of 1.5 psi, with an aqueous composition flow rate of 150 cc/min, an aqueous composition pH of 6.5, a platen speed of 52 RPM and a carrier spead of 50 RPM.

12. The aqueous composition of claim 9, wherein the aqueous composition is capable of reducing the step height on a patterned shallow trench isolation wafer to less than 50 Å, measured with an atomic force microscope, using a 200 mm polishing machine and a polyurethane polishing pad under a downforce condition of 1.5 psi, with an aqueous composition flow rate of 150 cc/min, an aqueous composition pH of 6.5, a platen speed of 52 RPM and a carrier spead of 50 RPM.

13. An aqueous composition useful for polishing silica and silicon nitride on a semiconductor wafer for shallow trench isolation processes consisting essentially of 0.01 to 5 wt % carboxylic acid polymer, 0.02 to 6 wt % abrasive, 0.01 to 10 wt % polyvinylpyrrolidone, 0.005 to 5 wt % cationic compound, 0.005 to 5 wt % zwitterionic compound and balance water; wherein the polyvinylpyrrolidone has a weight average molecular weight between 100 grams/mole to 1,000,000 grams/mole; and, wherein the aqueous composition is capable of reducing a step height on a patterned shallow trench isolation wafer.

14. The aqueous composition of claim 13, wherein the aqueous composition is capable of reducing the step height on a patterned shallow trench isolation wafer to less than 50 Å, measured with an atomic force microscope, using a 200 mm polishing machine and a polyurethane polishing pad under a downforce condition of 1.5 psi, with an aqueous composition flow rate of 150 cc/min, an aqueous composition pH of 6.5, a platen speed of 52 RPM and a carrier spead of 50 RPM.
